(19) United States
(12) Patent Application Publication
(10) Pub. No.: US 2024/0319604 A1
(43) Pub. Date: Sep. 26, 2024

(54) HYDROPHOBIC TREATMENT DEVICE AND METHOD FOR MANUFACTURING SEMICONDUCTOR DEVICE

(71) Applicant: Kioxia Corporation, Tokyo (JP)

(72) Inventor: Hirohito TANINO, Suzuka Mie (JP)

(73) Assignee: Kioxia Corporation, Tokyo (JP)

(21) Appl. No.: 18/588,597

(22) Filed: Feb. 27, 2024

(30) Foreign Application Priority Data
Mar. 23, 2023 (JP) 2023-046618

(51) Int. Cl. G03F 7/16; H01L 21/027

(52) U.S. Cl. CPC G03F 7/162; H01L 21/027

(57) ABSTRACT

A hydrophobic treatment device includes a placing table configured to place a substrate; a lid facing the placing table; a first supply port provided in the lid, and configured to discharge a hydrophobic gas with respect to the substrate; a second supply port provided in the lid, and configured to discharge an inert gas with respect to an outer periphery of the substrate; and a first adjustment mechanism configured to adjust a position of the second supply port with respect to the substrate by moving the lid in a radial direction of the substrate.

### CROSS-REFERENCE TO RELATED APPLICATION

This application is based upon and claims the benefit of priority from Japanese Patent Application No. 2023-046618, filed Mar. 23, 2023, the entire contents of which are incorporated herein by reference.

### FIELD

Embodiments described herein relate generally to a hydrophobic treatment device and a method for manufacturing a semiconductor device.

### BACKGROUND

In a semiconductor device manufacturing process, hydrophobic treatment is performed on the entire surface of a substrate in order to prevent a resist pattern from collapsing. However, when the hydrophobicity of the substrate increases, it may become difficult for a resist discharged near the center of the substrate to spread to the outer periphery of the substrate. Therefore, a coating abnormality may occur at the outer periphery of the substrate.

### DESCRIPTION OF THE DRAWINGS

FIG. 1 is a plan view showing a schematic example of a substrate treatment system according to an embodiment.

FIG. 2 is a cross-sectional view illustrating a state in which a substrate is held by a hydrophobic treatment device according to an embodiment.

FIG. 3 is a perspective view illustrating a configuration example of a base lid according to an embodiment.

FIG. 4 is a perspective view illustrating a configuration example of a lid according to an embodiment.

FIG. 5 is a perspective view illustrating a configuration example of a movable lid according to an embodiment.

FIG. 6 is a bottom view illustrating the configuration example of the movable lid according to the embodiment.

FIG. 7A and FIG. 7B illustrate a configuration example of a lid opening/closing drive mechanism according to an embodiment.

FIG. 8 is a flowchart showing an example of the procedure of a method for manufacturing a semiconductor device according to an embodiment.

FIG. 9A and FIG. 9B illustrate a configuration example of a lid according to a modification.

FIG. 10 is a view illustrating a substrate treated with a hydrophobic treatment device according to a comparative example.

### DETAILED DESCRIPTION

Embodiments provide a hydrophobic treatment device which can reduce hydrophobization of the outer periphery of a substrate during hydrophobic treatment, and a method for manufacturing a semiconductor device.

In general, according to one embodiment, a hydrophobic treatment device includes a placing table configured to place a substrate; a lid facing the placing table; a first supply port provided in the lid, and configured to discharge a hydrophobic gas with respect to the substrate; a second supply port provided in the lid, and configured to discharge an inert gas with respect to an outer periphery of the substrate; and a first adjustment mechanism configured to adjust a position of the second supply port with respect to the substrate by moving the lid in a radial direction of the substrate.

Hereafter, embodiments will be described in detail with reference to the drawings. The present disclosure is not limited by the embodiments to be described below. Components in the embodiments to be described below include those which may be easily imagined by those skilled in the art or those which are substantially the same.

### Embodiment

### Configuration Example of Substrate Treatment System

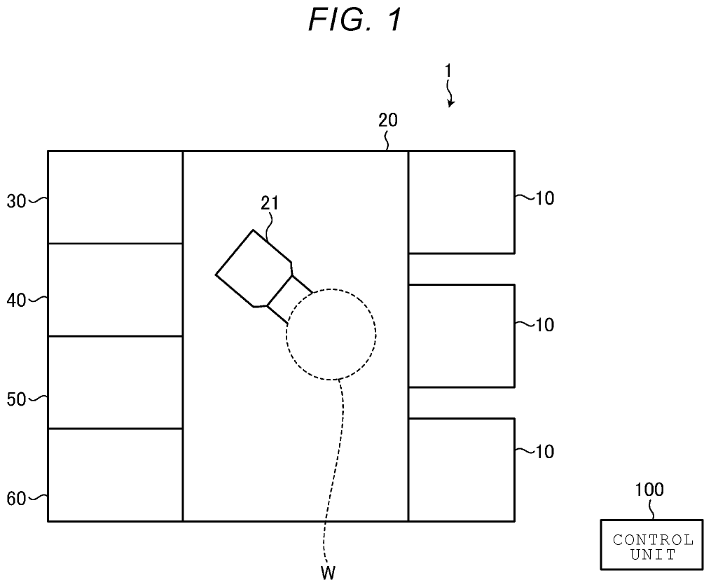

FIG. 1 is a plan view showing a schematic example of a substrate treatment system 1 according to an embodiment.

The substrate treatment system 1 of the embodiment is a system which performs hydrophobic treatment, forming of a photosensitive film, development of the photosensitive film after exposure, etc. for a substrate W. The substrate treatment system 1 is connected to an exposure device (not shown). By this fact, the substrate W on which the photosensitive film is formed is sent to the exposure device, and the substrate W after exposure is sent out from the exposure device.

As shown in FIG. 1, the substrate treatment system 1 includes a plurality of ports 10, a transfer room 20, a hydrophobic treatment device 30, a coating device 40, a heat treatment device 50, a development device 60, and a control unit 100.

The plurality of ports 10 accommodate a plurality of substrates W before and after treatment. The ports 10 are connected to the transfer room 20.

The transfer room 20 is a space for transferring the substrate W before and after treatment. A transfer arm 21 is provided in the transfer room 20. The transfer arm 21 sequentially transfers the substrate W between the transfer room 20, the ports 10, the hydrophobic treatment device 30, the coating device 40, the heat treatment device 50 and the development device 60. On a side of the transfer room 20 which oppositely faces the ports 10, the hydrophobic treatment device 30, the coating device 40, the heat treatment device 50 and the development device 60 are respectively provided adjacent to the transfer room 20.

The coating device 40 is a device which applies a chemical liquid as a coating liquid to the substrate W. The coating device 40 has a spinner (not illustrated). The spinner supports the substrate W which is subjected to hydrophobic treatment in the hydrophobic treatment device 30, and rotates on a horizontal plane. The spinner discharges the chemical liquid near the center of the substrate W while rotating the substrate W. The chemical liquid discharged near the center of the substrate W is applied to the substrate W while spreading toward the outer periphery of the substrate W. The chemical liquid includes an ingredient of a photosensitive film and a solvent in which the ingredient is dissolved. The photosensitive film is, for example, a resist film.

The heat treatment device 50 is a device which performs heat treatment on the substrate W. The heat treatment device 50 performs heat treatment, for example, on the substrate W which is coated with the chemical liquid in the coating device 40. By this fact, the solvent in the chemical liquid evaporates, and the ingredient in the chemical liquid is solidified. As a result, the photosensitive film is formed on the substrate W. Further, for example, the heat treatment device 50 performs heat treatment on the substrate W after exposure. By this fact, exposed portions of the photosensitive film become soluble in a developer.

The development device 60 is a device which performs developing treatment on the substrate W. The development device 60 applies the developer to the substrate W subjected to post-exposure heat treatment in the heat treatment device 50. Then, the development device 60 washes the developer with a rinse liquid. By this fact, a pattern is formed on the substrate W.

The control unit 100 controls each part of the substrate treatment system 1. The control unit 100 is configured with a computer including a CPU (central processing unit), a ROM (read only memory), a RAM (random access memory) and so forth (not shown), and controls the entire substrate treatment system 1. The control unit 100 controls respective devices including the ports 10, the transfer room 20, the hydrophobic treatment device 30, the coating device 40, the heat treatment device 50 and the development device 60.

### Configuration Example of Hydrophobic Treatment Device

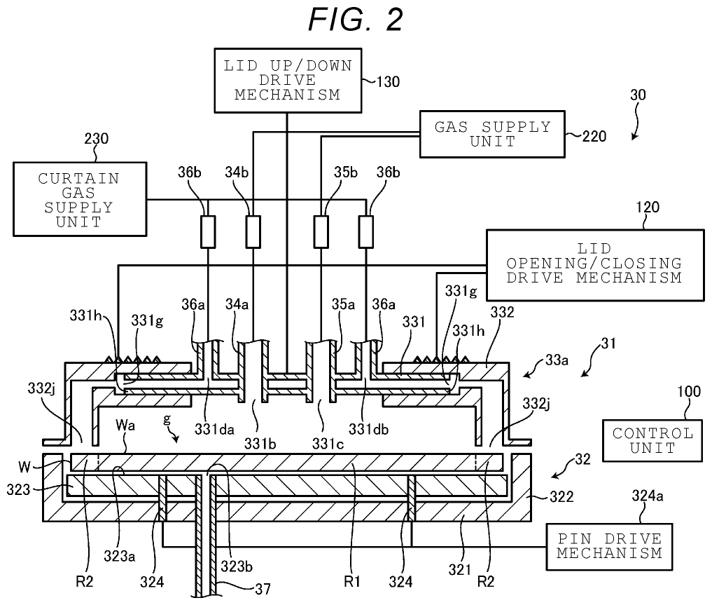

The configuration of the hydrophobic treatment device 30 will be described with reference to FIGS. 2 to 7. The hydrophobic treatment device 30 according to the embodiment is a device which performs hydrophobic treatment on the substrate W as a target for discharging the chemical liquid. The substrate W as a treatment target of the hydrophobic treatment device 30 has, for example, a lower layer film on a main surface Wa.

FIG. 2 is a cross-sectional view illustrating a state in which the substrate W is held by the hydrophobic treatment device 30 according to an embodiment.

In the present specification, a direction perpendicular to a hot plate 323 on which the substrate W may be placed is defined as a vertical direction. A direction in which a placing surface 323a of the hot plate 323 faces is defined as an upward direction, and an opposite direction is defined as a downward direction.

As illustrated in FIG. 2, the hydrophobic treatment device 30 includes a chamber 31, a lid opening/closing drive mechanism 120, a lid up/down drive mechanism 130, a gas supply unit 220, and a curtain gas supply unit 230.

The chamber 31 accommodates the substrate W, and performs hydrophobic treatment on the main surface Wa of the substrate W. The chamber 31 includes a treatment container 32, a lid 33a, a hydrophobic gas supply pipe 34a, a purge gas supply pipe 35a, two curtain gas supply pipes 36a, and an exhaust pipe 37.

The treatment container 32 accommodates the substrate W. The treatment container 32 includes a lower plate 321 which is horizontally disposed, a peripheral wall 322 which extends upward from the edge of the lower plate 321, the hot plate 323, and a plurality of support pins 324.

The hot plate 323 serving as a placing table may place the substrate W on its placing surface 323a. The hot plate 323 is disposed over the lower plate 321 and in the peripheral wall 322. The hot plate 323 is approximately disk-shaped when viewed from above. The hot plate 323 has a built-in heating wire (not illustrated), and is heated as electricity is supplied to the corresponding heating wire. Thereby, the hot plate 323 may heat the substrate W. The temperature of the hot plate 323 is, for example, 90° C. to 200° C.

An exhaust port 323b is formed in the placing surface 323a of the hot plate 323. The exhaust pipe 37 which passes through the hot plate 323 in the vertical direction is connected to the exhaust port 323b.

The exhaust pipe 37 may exhaust various gases in the chamber 31 to the outside. A vacuum pump (not illustrated) is connected to the exhaust pipe 37. Air, treatment gas (HMDS gas), N2 gas, etc. may flow through the exhaust pipe 37.

The plurality of support pins 324 may support the substrate W at their upper ends. The plurality of support pins 324 are configured to vertically pass through the hot plate 323 and be able to protrude upward from the placing surface 323a of the hot plate 323. The plurality of support pins 324 include a pin drive mechanism 324a. The plurality of support pins 324 are moved in the vertical direction by the pin drive mechanism 324a. As the plurality of support pins 324 are vertically moved, the substrate W vertically moves. By this fact, for example, the substrate W may be disposed on the hot plate 323.

The pin drive mechanism 324a is an actuator which includes a motor (not illustrated) or the like. The pin drive mechanism 324a controls the vertical movement of the plurality of support pins 324 according to an instruction from the control unit 100.

The lid 33a covers the upper opening of the treatment container 32. As the lid 33a covers the opening of the treatment container 32, a treatment space g is provided between the lid 33a and the substrate W placed on the hot plate 323. In other words, the lid 33a faces the substrate W across the treatment space g.

The lid 33a includes a base lid 331 as a first lid and a movable lid 332 as a second lid.

The base lid 331 is disposed at a position facing an inner region R1 of the substrate W placed on the hot plate 323. The base lid 331 supports the movable lid 332 at its edge.

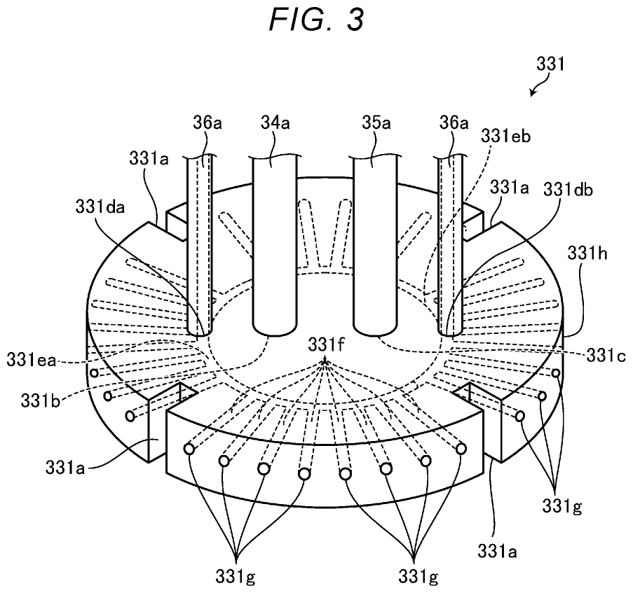

The detailed configuration of the base lid 331 will be described with reference to FIGS. 2 and 3. FIG. 3 is a perspective view illustrating a configuration example of the base lid 331 according to an embodiment. For the sake of convenience in explanation, other components such as the hydrophobic gas supply pipe 34a and so forth are also illustrated in FIG. 3.

The base lid 331 is formed into a flat plate shape with a substantially circle shape when viewed from above. As illustrated in FIG. 3, an edge 331h of the base lid 331 is formed with, for example, four recesses 331a which are recessed in a radial direction. The four recesses 331a are provided at approximately equal intervals in the circumferential direction of the base lid 331. By such four recesses 331a, the edge 331h of the base lid 331 is divided into four. The edge 331h is inserted into the movable lid 332 which will be described later.

As illustrated in FIGS. 2 and 3, the base lid 331 has supply ports 331b and 331c, openings 331da and 331db, through via holes 331ea, 331eb and 331f, and a plurality of connection holes 331g.

As illustrated in FIG. 2, the supply port 331b serving as a first supply port is provided on the lower surface of the base lid 331. The hydrophobic gas supply pipe 34a is connected to the supply port 331b.

The hydrophobic gas supply pipe 34a extends upward by vertically passing through the base lid 331 from the supply port 331b. The hydrophobic gas supply pipe 34a is connected to the gas supply unit 220 via a pressure regulator 34b. HMDS (hexamethyldisirazane) gas as a hydrophobic gas, which is a treatment gas supplied from the gas supply unit 220, passes through the hydrophobic gas supply pipe 34a and the pressure regulator 34b, and is discharged from the supply port 331b into the treatment space g.

As illustrated in FIG. 2, the supply port 331c is provided on the lower surface of the base lid 331. The purge gas supply pipe 35a is connected to the supply port 331c.

The purge gas supply pipe 35a extends upward by vertically passing through the base lid 331 from the supply port 331c. The purge gas supply pipe 35a is connected to the gas supply unit 220 via a pressure regulator 35b. N2 gas, which is a purge gas supplied from the gas supply unit 220, passes through the purge gas supply pipe 35a and the pressure regulator 35b, and is discharged from the supply port 331c into the treatment space g. Supply of N2 gas as a purge gas is performed after supply of HMDS gas is completed. By this fact, HMDS gas filled in the treatment space g is replaced with the purge gas, and HMDS gas is exhausted from the exhaust pipe 37 to the outside.

As illustrated in FIGS. 2 and 3, the openings 331da and 331db are provided on the upper surface of the base lid 331. The curtain gas supply pipes 36a are connected to the openings 331da and 331db, respectively.

The curtain gas supply pipes 36a extend upward from the openings 331da and 331db, respectively, and are connected to the curtain gas supply unit 230 via regulators 36b. N2 gas as an inert gas supplied from the curtain gas supply unit 230 passes through the regulators 36b and the curtain gas supply pipes 36a, and is sent to the openings 331da and 331db.

As illustrated in FIG. 3, the openings 331da and 331db are connected to the two through via holes 331ea and 331eb, respectively, through the inside of the base lid 331.

The through via holes 331ea and 331eb extend along the inside of the base lid 331 in a circumferential direction from the openings 331da and 331db, respectively, and then, are connected to the plurality of through via holes 331f by branching in the radial direction. The plurality of through via holes 331f are connected to the plurality of connection holes 331g, respectively, which are provided on the side surface of the base lid 331.

The plurality of connection holes 331g are approximately circular holes which open on the side surface of the base lid 331. The plurality of connecting holes 331g are formed on the side surface of the base lid 331 at approximately equal intervals. Among the plurality of connection holes 331g, the half of the connection holes 331g communicate with the opening 331da via the through via holes 331f and the through via hole 331ea. The remaining connection holes 331g communicate with the opening 331db via the through via holes 331f and the through via hole 331eb. In this way, N2 gas sent from the curtain gas supply unit 230 to the openings 331da and 331db is sent to the plurality of connection holes 331g.

In the example of FIGS. 2 and 3, it was described that the base lid 331 has two openings 331da and 331db and two through via holes 331ea and 331eb, but the present disclosure is not limited thereto. The base lid 331 may have any configuration as long as it is possible to send out N2 gas supplied from the curtain gas supply unit 230.

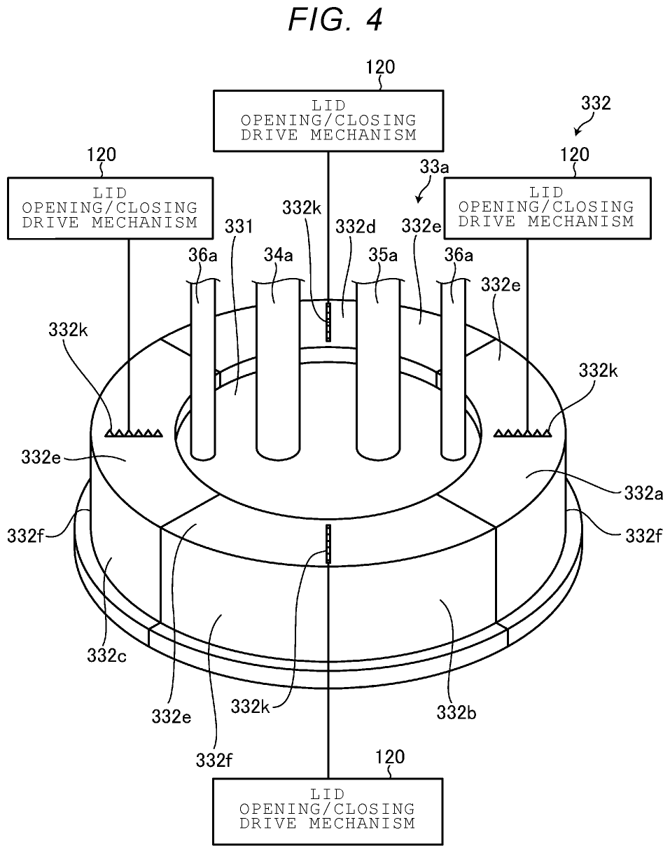

The detailed configuration of the movable lid 332 will be described with reference to FIGS. 4 to 6. FIG. 4 is a perspective view illustrating a configuration example of the lid 33a according to an embodiment.

As illustrated in FIG. 4, the movable lid 332 is configured with, for example, four movable lids 332a to 332d. The movable lids 332a to 332d as child lids are connected to the outside of the base lid 331.

Each of the movable lids 332a to 332d has a flat surface part 332e which extends along the base lid 331, and a side surface part 332f which extends downward by being bent from the outer end of the flat surface part 332e.

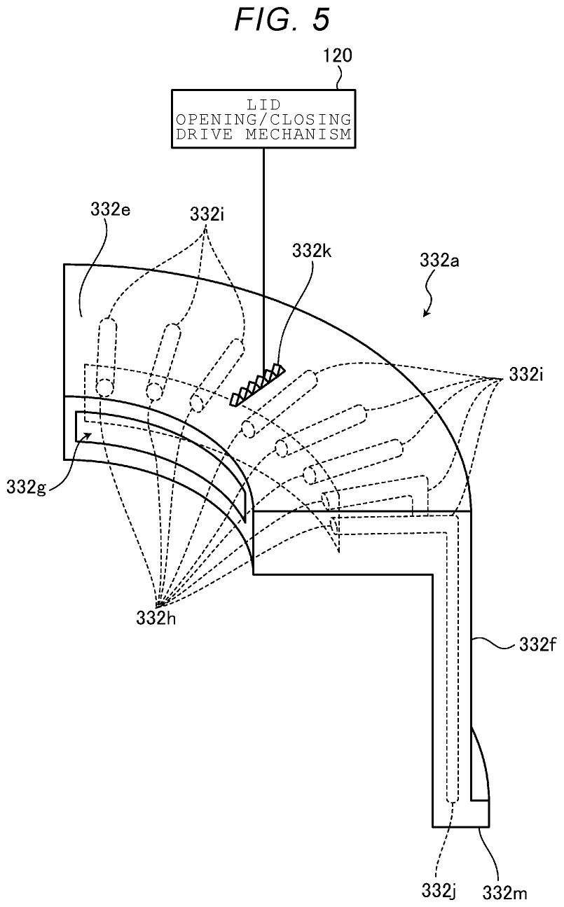

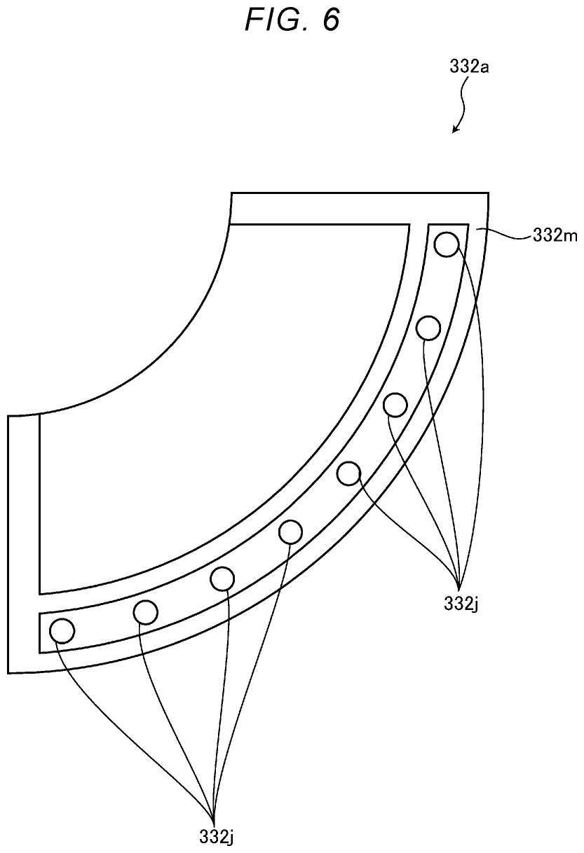

FIG. 5 is a perspective view illustrating a configuration example of the movable lid 332a according to an embodiment. FIG. 6 is a bottom view illustrating the configuration example of the movable lid 332a according to the embodiment. That is to say, FIG. 6 is a view taken when viewing the movable lid 332a of FIG. 5 from an end 332m.

As illustrated in FIGS. 5 and 6, the movable lid 332a includes a recess 332g, a plurality of connection holes 332h, a plurality of through via holes 332i, a plurality of supply ports 332j, and a drive unit 332k.

The recess 332g illustrated in FIG. 5 is a portion which is connected with the base lid 331 (FIG. 3). The recess 332g is formed such that the flat surface part 332e of the movable lid 332a is recessed toward the outside in a radial direction. As the edge 331h (FIG. 3) of the base lid 331 is inserted into such a recess 332g, the base lid 331 and the movable lid 332 are connected. In the recess 332g, the base lid 331 and the movable lid 332 vertically overlap. By this fact, even when the movable lid 332 and the base lid 331 relatively move, the connection between the movable lid 332 and the base lid 331 is maintained. The plurality of connection holes 332h are formed on the side surface of the recess 332g which faces inward in the radial direction.

The plurality of connection holes 332h are formed at positions corresponding to the plurality of connection holes 331g (FIG. 3) which are formed on the side surface of the base lid 331. As the edge 331h of the base lid 331 is inserted into the recess 332g, the connection holes 331g of the base lid 331 and the connection holes 332h of the movable lid 332a may communicate with each other in the recess 332g. The plurality of connection holes 332h are connected to the plurality of through via holes 332i, respectively, which pass through the inside of the movable lid 332a.

Each of the plurality of through via holes 332i extends from each of the connection holes 332h along the flat surface part 332e of the movable lid 332a in the radial direction, and is then bent downward along the side surface part 332f. Each of the plurality of through via holes 332i is connected to each of the plurality of supply ports 332j which are formed at the end 332m of the side surface part 332f.

As illustrated in FIG. 6, the supply ports 332j as second supply ports are approximately circular holes which are open at the end 332m of the movable lid 332a. The supply ports 332j are circumferentially disposed at approximately equal intervals along the end 332m. The supply ports 332j face an outer region R2 (FIG. 2) as the outer periphery of the substrate W which is placed on the hot plate 323.

Summarizing the above description, the base lid 331 and the movable lid 332 are connected at the recesses 332g of the movable lid 332. The openings 331da and 331db of the base lid 331 and the supply ports 332j formed at the end 332m of the movable lid 332 communicate with each other via the connection holes 331g of the base lid 331 and the connection holes 332h of the movable lid 332. By this fact, N2 gas supplied from the curtain gas supply unit 230 passes through the insides of the base lid 331 and the movable lid 332, and is discharged from the supply ports 332j to the outer region R2 of the substrate W.

Returning to FIG. 5, the drive unit 332k of the movable lid 332 is a member in which a plurality of recesses and a plurality of protrusions are alternately located. The recesses and protrusions of the drive unit 332k are configured to mesh with the lid opening/closing drive mechanism 120, which will be described later. The drive unit 332k is disposed on the upper surface of the flat surface part 332e of each of the movable lids 332a to 332d SO that a direction in which the recesses and the protrusions are located is along the radial direction. The drive unit 332k is connected to the lid opening/closing drive mechanism 120 as a first adjustment mechanism.

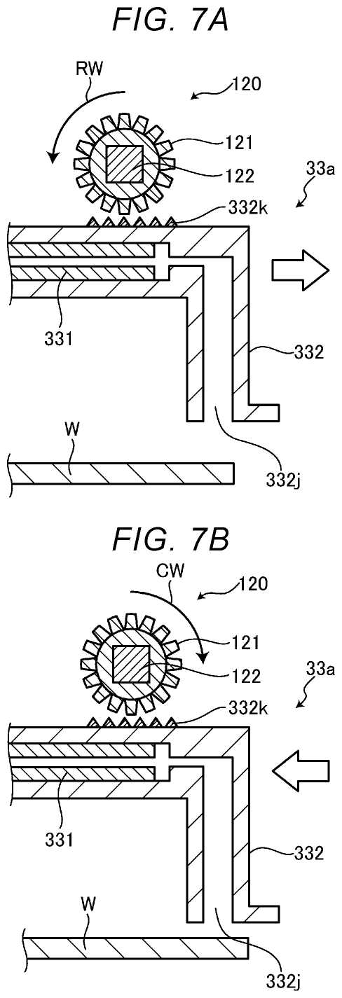

FIG. 7 is a view illustrating a configuration example of the lid opening/closing drive mechanism 120 according to an embodiment. FIG. 7 illustrates a part of the configuration of the lid opening/closing drive mechanism 120 and a half sectional view of the lid 33a and the substrate W facing the lid 33a.

As illustrated in FIG. 7, the lid opening/closing drive mechanism 120 includes a gear 121 and a motor 122. The gear 121 may be rotated, by the motor 122, about a rotation shaft (not illustrated) which extends in the circumferential direction of the substrate W. The gear 121 is configured to mesh with the recesses and protrusions of the drive unit 332k disposed on the upper surface of the movable lid 332. Although not illustrated, such a lid opening/closing drive mechanism 120 is supported, for example, from the upper surface of the hydrophobic treatment device 30.

As illustrated in FIG. 7A, for example, the lid opening/closing drive mechanism 120 operates the motor 122 according to an instruction of the control unit 100 to rotate the gear 121 in a direction RW. Then, the movable lid 332 moves with respect to the base lid 331 in the direction of the arrow, that is, toward the outside of the substrate W in the radial direction. By this, the positions of the supply ports 332j with respect to the substrate W also move toward the outside in the radial direction.

As illustrated in FIG. 7B, for example, the lid opening/closing drive mechanism 120 rotates the gear 121 in a direction CW. Then, the movable lid 332 moves with respect to the base lid 331 in the direction of the arrow, that is, toward the inside in the radial direction. By this, the positions of the supply ports 332j with respect to the substrate W also move toward the inside in the radial direction.

Returning to FIG. 2, the lid up/down drive mechanism 130 is an actuator which includes a motor (not illustrated) or the like. As illustrated in FIG. 2, the lid up/down drive mechanism 130 is connected to the base lid 331. The lid up/down drive mechanism 130 controls the operation of the base lid 331 in the vertical direction according to an instruction from the control unit 100. Thereby, the lid 33a may move up and down with respect to the treatment container 32.

The gas supply unit 220 supplies HMDS gas according to an instruction of the control unit 100. HMDS gas is discharged into the treatment space g through the hydrophobic gas supply pipe 34a and the supply port 331b. By this, the treatment space g is filled with HMDS gas, and the substrate W is hydrophobicized. The control unit 100 adjusts the supply amount of HMDS gas with respect to the treatment space g by controlling the pressure regulator 34b.

The gas supply unit 220 also functions as a supply unit which supplies N2 gas for purging HMDS gas filled in the treatment space g. The gas supply unit 220 supplies N2 gas as a purge gas according to an instruction of the control unit 100. N2 gas is discharged into the treatment space g through the purge gas supply pipe 35a and the supply port 331c. By this, HMDS gas filled in the treatment space g is exhausted from the exhaust pipe 37. The control unit 100 adjusts the supply amount of N2 gas with respect to the treatment space g by controlling the pressure regulator 35b.

The curtain gas supply unit 230 supplies N2 gas according to an instruction from the control unit 100. N2 gas passes through the insides of the curtain gas supply pipes 36a, the base lid 331 and the movable lid 332, and is discharged toward the outer region R2 of the substrate W from the supply ports 332j. By this fact, a so-called air curtain is formed between the supply ports 332j and the outer region R2 of the substrate W. Namely, the outer region R2 of the substrate W and the upper part of the outer region R2 are covered with N2 gas.

The curtain gas supply unit 230 supplies N2 gas when HMDS gas is being supplied from the gas supply unit 220, according to an instruction from the control unit 100. By this fact, the outer region R2 of the substrate W is shielded from HMDS gas filled in the treatment space g by N2 gas. As a result, hydrophobization of the outer region R2 is prevented.

### (Method for Manufacturing Semiconductor Device)

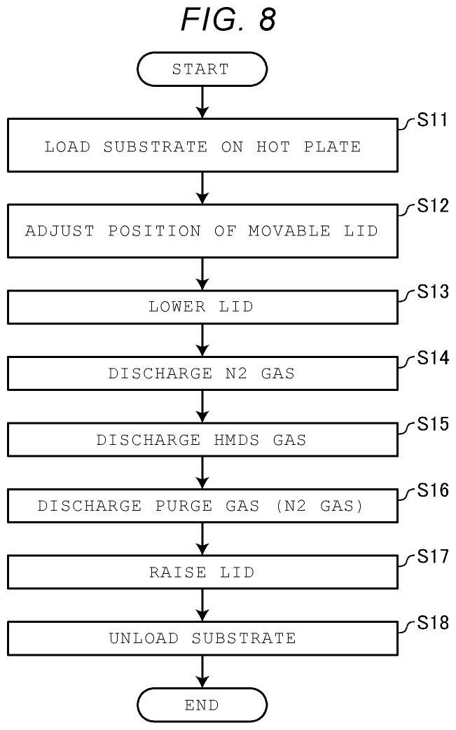

FIG. 8 is a flowchart showing an example of the procedure of a method for manufacturing a semiconductor device according to an embodiment. In FIG. 8, as one process of the method for manufacturing a semiconductor device, an example of performing hydrophobic treatment on the substrate W as a treatment target, on which a photosensitive film is to be formed, will be described. The hydrophobic treatment of the substrate W in the hydrophobic treatment device 30 is performed as a part of the method for manufacturing a semiconductor device.

Prior to treatment of S11, the substrate W is transferred from the port 10 to the transfer room 20 by the transfer arm 21.

The substrate W is introduced into the hydrophobic treatment device 30. Specifically, first, prior to the introduction of the substrate W, the control unit 100 operates the lid up/down drive mechanism 130 to raise the lid 33a. The control unit 100 operates the pin drive mechanism 324a to move the plurality of support pins 324 upward.

Next, the transfer arm 21 which holds the substrate W enters the chamber 31. When the support pins 324 and the substrate W come into contact with each other, the transfer arm 21 places the substrate W on the support pins 324, and exits the chamber 31. As the support pins 324 are lowered to original positions, the substrate W is disposed on the hot plate 323 (S11), and introduction of the substrate W is completed.

Next, positions of the supply ports 332j of the movable lid 332 with respect to the substrate W are adjusted. Specifically, the control unit 100 operates the lid opening/closing drive mechanism 120, moves the movable lid 332 with respect to the base lid 331 in the radial direction, and adjusts the positions of the supply ports 332j (S12). Regarding the positions of the supply ports 332j and other conditions, desired positions and conditions may be selected by loading a recipe prepared in advance by a user of the substrate treatment system 1 or the like.

Next, when the adjustment of the supply ports 332j is completed, the control unit 100 operates the lid up/down drive mechanism 130 to lower the lid 33a (S13).

Next, the control unit 100 controls the curtain gas supply unit 230 to discharge N2 gas from the supply ports 332j with respect to the outer region R2 of the substrate W (S14).

Next, the control unit 100 controls the gas supply unit 220 to discharge HMDS gas from the supply port 331b of the base lid 331 (S15). By this fact, the substrate W is hydrophobicized. At this time, the outer region R2 of the substrate W which vertically overlaps the supply ports 332j is shielded by N2 gas. Therefore, hydrophobization of the outer region R2 of the substrate W is prevented. The control unit 100 ends the supply of HMDS gas after a predetermined period of time (for example, 30 seconds) elapses.

Next, the control unit 100 controls the gas supply unit 220 to discharge N2 gas as a purge gas from the supply port 331c after the supply of HMDS gas is completed (S16). By this, HMDS gas is exhausted. The control unit 100 ends the supply of N2 gas after a predetermined period of time (for example, 10 seconds) elapses.

Next, the control unit 100 operates the lid up/down drive mechanism 130 to raise the lid 33a (S17). The control unit 100 operates the pin drive mechanism 324a to move the plurality of support pins 324 upward. Thereby, the substrate W is lifted from the hot plate 323.

Next, the transfer arm 21 enters the chamber 31. When the transfer arm 21 is disposed below the substrate W, the support pins 324 are lowered to the original positions by the pin drive mechanism 324a. Thereby, the substrate W is transferred from the support pins 324 to the transfer arm 21. The transfer arm 21 which holds the substrate W exits the chamber 31. By this fact, unloading of the substrate W is completed (S18). In this way, hydrophobic treatment of the substrate W in the hydrophobic treatment device 30 ends.

After that, the transfer arm 21 transfers the substrate W to the coating device 40. The coating device 40 coats the substrate W with a chemical liquid for a photosensitive film, as a coating liquid.

The transfer arm 21 transfers the substrate W coated with the photosensitive film in the coating device 40 to the heat treatment device 50. The heat treatment device 50 performs heat treatment on the substrate W. By this fact, the photosensitive film is formed on the substrate W.

The transfer arm 21 transfers the substrate W formed with the photosensitive film in the heat treatment device 50 to an exposure device, and transfers the substrate W after exposure to the heat treatment device 50 again.

The transfer arm 21 transfers the substrate W which is heat-treated again in the heat treatment device 50, to the development device 60. By this fact, a pattern is formed. With this, manufacturing of a semiconductor device ends.

### Comparative Example

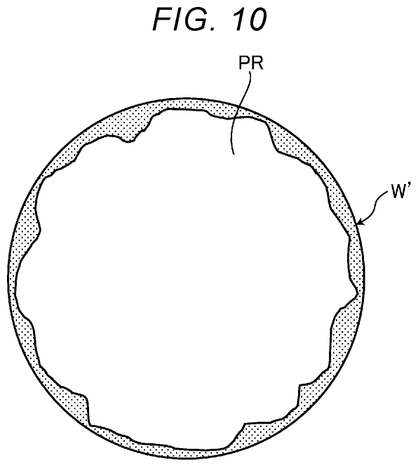

A hydrophobic treatment device according to a comparative example will be described using FIG. 10. FIG. 10 is a view illustrating a substrate W′ treated with the hydrophobic treatment device according to the comparative example. FIG. 10 illustrates a state in which a chemical liquid PR is applied to the substrate W′ hydrophobicized in the hydrophobic treatment device according to the comparative example.

In the hydrophobic treatment device according to the comparative example, the substrate W′ is hydrophobicized on the entire surface thereof. When the substrate W′ is hydrophobicized, the contact angle of the substrate W′ increases. Therefore, wettability of the chemical liquid PR of the photosensitive film may decrease. If wettability of the chemical liquid PR decreases, it becomes difficult for the chemical liquid PR discharged near the center of the substrate W′ to spread to the outer periphery of the substrate W′. As a result, for example, as illustrated in FIG. 10, a coating abnormality in which a portion of the outer periphery of the substrate W′ is not covered with the chemical liquid PR may occur. However, if the substrate W′ is not hydrophobicized, adhesion between the substrate W′ and the photosensitive film may deteriorate, and when a pattern is formed, the corresponding pattern is likely to collapse.

### (Overview)

The hydrophobic treatment device 30 according to the embodiment has the lid 33a. The lid 33a includes the supply port 331b which discharges HMDS gas with respect to the substrate W, and the supply ports 332j which discharge N2 gas to the outer region R2 of the substrate W when HMDS gas is discharged. Furthermore, the hydrophobic treatment device 30 according to the embodiment includes the lid opening/closing drive mechanism 120 which may adjust the positions of the supply ports 332j with respect to the substrate W.

Specifically, the lid 33a has the base lid 331 and the movable lid 332 which has the supply ports 332j. The movable lid 332 is configured with the plurality of movable lids 332a to 332d. As each of the movable lids 332a to 332d connected to the lid opening/closing drive mechanism 120 moves in the radial direction of the substrate W, the positions of the supply ports 332j with respect to the substrate W move. By this, in the hydrophobic treatment of the substrate W, it is possible to prevent hydrophobization of the outer region R2 of the substrate W. As a result, an abnormality in coating the chemical liquid in the outer region R2 may be avoided.

The lid opening/closing drive mechanism 120 according to the embodiment has the gear 121 which is connected to the rotation shaft extending in the circumferential direction of the substrate W. The movable lid 332 has the drive unit 332k which meshes with the gear 121. The lid opening/closing drive mechanism 120 rotates the gear 121 in the radial direction according to an instruction from the control unit 100. By this, the movable lid 332 may move along the radial direction of the substrate W with respect to the base lid 331.

### Modification

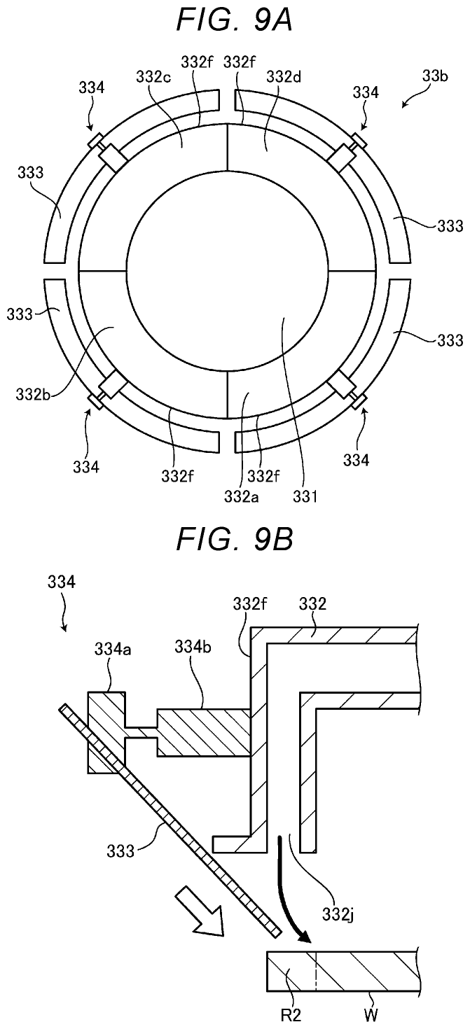

Hereinafter, a modification of the above embodiment will be described in detail with reference to FIG. 9. A hydrophobic treatment device according to the modification differs from the above embodiment in that the movable lid 332 includes rectifier plates 333 and rectifier plate drive mechanisms 334.

In the following description, the same reference symbols may be used to refer to the same configuration as the above embodiment, and description thereof may be omitted.

FIG. 9 is a view illustrating a configuration example of a lid according to a modification. FIG. 9A is a plan view of the lid 33b. FIG. 9B is a half-sectional view of the movable lid 332 and the substrate W facing the movable lid 332.

As illustrated in FIG. 9, each of the four movable lids 332a to 332d has the rectifier plate 333 and the rectifier plate drive mechanism 334.

The rectifier plate 333 is a plate-shaped member which is made of, for example, metal. As illustrated in FIG. 9A, when viewed from above, the rectifier plate 333 is disposed along the outside of each of the movable lids 332a to 332d. Further, as illustrated in FIG. 9B, when viewed from the side, the rectifier plate 333 extends toward the substrate W from the outside of each of the movable lids 332a to 332d.

As illustrated in FIG. 9B, the rectifier plate drive mechanism 334 as a second adjustment mechanism is an actuator which includes a motor 334a. The rectifier plate drive mechanism 334 is disposed on the side surface part 332f of each of the movable lids 332a to 332d. The rectifier plate drive mechanism 334 supports the rectifier plate 333 by a support portion 334b.

The rectifier plate drive mechanism 334 operates the motor 334a according to an instruction of the control unit 100 to relatively move the rectifier plate 333 with respect to the outer region R2 of the substrate W. As the rectifier plate 333 is inserted between the supply ports 332j and the outer region R2 of the substrate W, flow of N2 gas discharged from the supply ports 332j is directed inward in the radial direction of the substrate W. By this fact, N2 gas is discharged to a region slightly inward of the outer region R2 of the substrate W.

The control unit 100 controls the rectifier plate drive mechanism 334, and adjusts the position of the rectifier plate 333 with respect to the substrate W. Thereby, flow of N2 gas discharged from the supply ports 332j is changed, and the discharge positions of N2 gas with respect to the substrate W are adjusted. The control unit 100 may control both the rectifier plate drive mechanism 334 and the lid opening/closing drive mechanism 120 to adjust the discharge positions of N2 gas.

The disposition positions of the rectifier plate 333 and the rectifier plate drive mechanism 334 are not limited to the above example. For example, one rectifier plate 333 and one rectifier plate drive mechanism 334 may be provided for one supply port 332j.

### Other Modifications

In the above-described embodiment and modification, it was described that N2 gas is delivered to the supply ports 332j through the through via holes 331e and 331f, the through via holes 331ea and 331eb, etc. formed in the lid 33a. However, instead of these through via holes, a piping may be built in the lid 33a. N2 gas may be delivered to the supply ports 332j via the piping extending in the lid 33a.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A hydrophobic treatment device comprising:
a placing table configured to place a substrate;
a lid facing the placing table;
a first supply port provided in the lid, and configured to discharge a hydrophobic gas with respect to the substrate;
a second supply port provided in the lid, and configured to discharge an inert gas with respect to an outer periphery of the substrate; and
a first adjustment mechanism configured to adjust a position of the second supply port with respect to the substrate by moving the lid in a radial direction of the substrate.

2. The hydrophobic treatment device of claim 1, wherein the lid comprises:
a first lid facing a region around the outer periphery of the substrate; and
a second lid having the second supply port, and connected to an outside of the first lid.

3. The hydrophobic treatment device of claim 2, wherein the second lid comprises:
child lids each having a flat surface part connected to the outside of the first lid and extending along the first lid, and a side surface part bent downward from an outer end of the flat surface part,
wherein the second supply port is provided at an end of the side surface part facing the substrate, and
wherein each of the child lids is configured to adjust a position of the second supply port with respect to the substrate by moving in a radial direction of the substrate.

4. The hydrophobic treatment device of claim 3, wherein
the child lid has, on an upper surface of the flat surface part, a drive unit having recesses and protrusions alternately located in the radial direction of the substrate,
the first adjustment mechanism has a gear connected to a rotation shaft extending in a circumferential direction of the substrate and configured to rotate about the rotation shaft in the radial direction of the substrate, and
the child lid is configured to move in the radial direction of the substrate e while the recesses and protrusions of the drive unit mesh with the gear.

5. The hydrophobic treatment device of claim 2, wherein the second lid comprises:
a rectifier plate extending from an outside of the second lid toward the substrate; and
a second adjustment mechanism provided on the second lid to support the rectifier plate, and configured to adjust a discharge position of the inert gas with respect to the outer periphery of the substrate by moving the rectifier plate with respect to the substrate.

6. A method for manufacturing a semiconductor device, comprising:
placing, on a placing table, a substrate;
adjusting a position of a second supply port, provided in a lid, with respect to the substrate by moving the second supply port in a radial direction of the substrate;
disposing the lid to face the placing table;
discharging an inert gas from the second supply port with respect to an outer periphery of the substrate;
discharging, through a first supply port provided in the lid, a hydrophobic gas with respect to the substrate;
treating the substrate with the hydrophobic gas while shielding the substrate from the hydrophobic gas by the inert gas; and
applying a coating liquid to the substrate.

7. The method of claim 6, wherein the coating liquid is configured to form a photosensitive film over the substrate.

8. The method of claim 6, wherein the lid comprises:
a first lid facing a region around the outer periphery of the substrate; and
a second lid having the second supply port, and connected to an outside of the first lid.

9. The method of claim 8, wherein the second lid comprises:
child lids each having a flat surface part connected to the outside of the first lid and extending along the first lid, and a side surface part bent downward from an outer end of the flat surface part,
wherein the second supply port is provided at an end of the side surface part facing the substrate, and
wherein each of the child lids is configured to adjust a position of the second supply port with respect to the substrate by moving in a radial direction of the substrate.

10. The method of claim 9, wherein
the child lid has, on an upper surface of the flat surface part, a drive unit having recesses and protrusions alternately located in the radial direction of the substrate,
the first adjustment mechanism has a gear connected to a rotation shaft extending in a circumferential direction of the substrate and configured to rotate about the rotation shaft in the radial direction of the substrate, and
the child lid is configured to move in the radial direction of the substrate while the recesses and protrusions of the drive unit mesh with the gear.

11. The method of claim 8, wherein the second lid comprises:
a rectifier plate extending from an outside of the second lid toward the substrate; and
a second adjustment mechanism provided on the second lid to support the rectifier plate, and configured to adjust a discharge position of the inert gas with respect to the outer periphery of the substrate by moving the rectifier plate with respect to the substrate.
